(19) United States
(12) Patent Application Publication
(10) Pub. No.: US 2006/0141169 A1
(43) Pub. Date: Jun. 29, 2006

(54) Method and apparatus for vacuum deposition

(75) Inventors: Yukihisa Noguchi, Kanagawa (JP); Makoto Kashiwaya, Kanagawa (JP); Hiroshi Matsumoto, Kanagawa (JP)

Correspondence Address: SUGHRUE MION, PLLC, 2100 PENNSYLVANIA AVENUE, N.W., SUITE 800, WASHINGTON, DC, 20037, US

(73) Assignee: FUJI PHOTO FILM CO., LTD.

(21) Appl. No.: 11/289,571

(22) Filed: Nov. 30, 2005

(30) Foreign Application Priority Data
Nov. 30, 2004 (JP) 2004-346832

(51) Int. Cl. C23C 8/00; C23C 16/00; B05C 11/00

(52) U.S. Cl. 427/585; 118/726; 118/666

(57) ABSTRACT

The vacuum deposition method measures temperature in an interior of a crucible for the resistance heating which contains at least one film-depositing material, controls heating of the crucible in accordance with a measurement result of the temperature and forming a film on a substrate under controlling of the heating of the crucible. The vacuum deposition apparatus includes a vacuum chamber, an evacuating unit for evacuating the vacuum chamber, one or more crucibles for resistance heating, a power source for resistance heating which supplies the at least one crucible with resistance heating power, a temperature measuring unit for measuring the temperature in an interior of at least one crucible and a controller for controlling supply of power for resistance heating to one or more crucibles in accordance with the measurement result of the temperature.

The entire contents of literatures cited in this specification are incorporated herein by reference.

### BACKGROUND OF THE INVENTION

This invention relates to the technical field of vacuum deposition, more particularly, to a method and apparatus by which the deposition rate can be controlled with high precision.

Upon exposure to a radiation (e.g. X-rays, α-rays, β-rays, γ-rays, electron beams, and ultraviolet rays), certain types of phosphors known in the art accumulate part of the energy of the applied radiation and, in response to subsequent application of excitation light such as visible light, they emit photostimulated luminescence in an amount that is associated with the accumulated energy. Called “storage phosphors” or “stimulable phosphors”, those types of phosphors find use in medical and various other fields.

A known example of such use is a radiation image information recording and reproducing system that employs a sheet having a layer of the stimulable phosphor (which is hereinafter referred to as a phosphor layer) and the sheet is hereinafter referred to as a phosphor sheet (also called a radiation image converting sheet). The system has already been commercialized by, for example, Fuji Photo Film Co., Ltd. under the trade name FCR (Fuji Computed Radiography).

In this system, radiation image information about a subject such as the human body is recorded in the phosphor sheet (phosphor layer), which is thereafter irradiated with excitation light to emit photostimulated luminescence which in turn is read photoelectrically to issue an image signal, on the basis of which an image is reproduced and outputted as a radiation image of the subject, typically on a display device such as CRT or in a recording material such as a photographic light-sensitive material.

The phosphor sheet under consideration is typically prepared by the following method: Powder of an storage phosphor is dispersed in a solvent containing a binder and other necessary ingredients to make a coating solution, which is applied to a sheet of support typically made of glass or a resin, with the applied coating being subsequently dried.

Also known are phosphor sheets of the type described in JP 2,789,194 B and JP 5-249299 A which are prepared by forming a phosphor layer on a support through physical vapor deposition (vapor-phase film deposition) such as vacuum deposition. The phosphor layer formed by vapor deposition has superior characteristics in that it is formed in vacuum and hence has low impurity levels and that being substantially free of any ingredients other than the storage phosphor as exemplified by a binder, the phosphor layer has not only small scatter in performance but also features very highly efficient luminescence.

A vacuum deposition method is known that is capable of forming a phosphor layer that has a satisfactory columnar crystal structure and which can produce high photostimulated luminescence characteristics as well as very sharp image; the method comprises performing vapor deposition in a comparatively low degree of vacuum of about 1-10 Pa with an inert gas being introduced (see, for example, US 2001/0010831 A1).

In order to ensure that an appropriate film having a predetermined thickness is formed consistently by vacuum deposition, it is important that the amount of a film-depositing material being evaporated from a crucible (i.e. the evaporation rate), or the vapor deposition rate, be controlled in an appropriate manner.

In the aforementioned phosphor sheets, the thickness of the phosphor layer is usually about 500 μm, sometimes in excess of 1000 μm. In addition, in medical fields such as where FCR is employed, an inappropriate film thickness will result in an inappropriate distance between a sensor that is to read photostimulated luminescence and the surface of the phosphor layer, causing image deterioration such as a blurry image. Such image deterioration is a potential cause of an error in diagnosis. Therefore, if a phosphor sheet is to be produced by forming a phosphor layer through vacuum deposition, the deposition rate needs to be controlled with high precision.

A method known in the art as a means of controlling the amount of evaporation in vacuum deposition includes direct measurement of the amount of evaporation of a film-depositing material with a quartz crystal monitor and feeding back the result of the measurement to control the heating with a heating source, thereby controlling the amount of evaporation.

Also known is a method in which temperature measurement is conducted and the result of the measurement is fed back to control the heating with a thermal evaporation source, thereby controlling the amount of evaporation.

For example, JP 6-158287 A discloses a method of vacuum deposition by resistance heating, in which temperature measurement is performed with a thermocouple in contact with the outer bottom surface of a resistance heating source [a boat (crucible) for evaporation by resistance heating] and heating is controlled in accordance with the result of the measurement. JP 7-331421 A discloses the use of a radiation thermometer and JP 2000-34559 A discloses the use of a temperature sensor, both for measuring the temperature in the internal space of a vacuum chamber (film depositing system) and controlling heating in accordance with the result of the measurement.

A problem with the method using a quartz crystal monitor is that when a thick film such as a phosphor sheet is to be formed, the film-depositing material builds up in the sensor portion, leading to gradual decrease in precision. When film deposition is performed in a comparatively low degree of vacuum with an inert gas being introduced as disclosed in US 2001/0010831 A1, the gas particles collide with the evaporated particles of the film-depositing material to prevent the latter from reaching the sensor portion of the quartz crystal monitor, again leading to a failure to perform highly precise measurement.

According to the method disclosed in JP 6-158287 A where temperature measurement is performed with a thermocouple in contact with the outer bottom surface of a crucible, changes in the degree of contact between the thermocouple and the outer bottom surface of the crucible, effects of the external environment, and other factors prevent consistent temperature measurement. In addition, the results of temperature measurement with the thermocouple are affected by the unwanted small voltage coming from the power source for resistance heating and this again makes it impossible to know the temperature of the film-depositing material with adequate precision.

Referring to the methods disclosed in JP 7-331421 A and JP 2000-34559 A, which control heating in accordance with the result of temperature measurement in the film depositing system, the result of temperature measurement is strongly affected by various elements in the film depositing system, so it is difficult to know the temperature of the molten film-depositing material in a consistent and appropriate manner and, hence, temperature control, or control of the amount of evaporation cannot be effected with adequate precision.

### SUMMARY OF THE INVENTION

The present invention has been accomplished in order to solve the aforementioned conventional problems and has as an object providing a method of vacuum deposition in which the temperature of a molten film-depositing material (melt evaporation source) is known in an appropriate and consistent manner in film formation by vacuum deposition and in which appropriate feedback control is effected in accordance with the result of the temperature thus known, so that the amount of evaporation of the film-depositing material, or the deposition rate is controlled with sufficiently high precision to ensure that a film of a predetermined thickness can be formed in a consistent manner. The method is optimal, typically for producing storage phosphor sheets by forming the phosphor layer through vacuum deposition.

Another object of the present invention is to provide an apparatus for vacuum deposition that can be used to implement the stated method of vacuum deposition.

In order to achieve the object, according to a first aspect of the present invention, there is provided a method of vacuum deposition involving resistance heating, including the steps of: measuring temperature in an interior of a crucible for the resistance heating which contains at least one film-depositing material; controlling heating of said crucible in accordance with a measurement result of the temperature of said interior of said crucible; and forming a film on a surface of a substrate under controlling of the heating of said crucible.

In the method of vacuum deposition according to the first aspect of the present invention, it is preferable that said heating of said crucible is performed by applying electric current to said crucible from a power source to generate heat by itself. Further, it is preferable that said crucible comprises a film-depositing material containing section having an interior space for containing said at least one film-depositing material which is a substantially closed space and a vapor outlet having an aperture ratio of not more than 10%. Further, it is preferable that said crucible further comprises a tubular section that surrounds said vapor outlet and which projects from said film-depositing material containing section. Further, it is preferable that a shield member that prevents said at least one film-depositing material from gushing out upon bumping is provided within said film-depositing material containing section. Further, it is preferable that said temperature in said interior of said crucible is measured in an area between said shield member and said vapor outlet or on a side of said vapor outlet with respect to said shield member. Further, it is preferable that The method of vacuum deposition according to claim 1, wherein said temperature in said interior of said crucible is measured in a position which at all times is out of contact with a molten film-depositing material of said at least one film-depositing material. Further, it is preferable that said temperature in said interior of said crucible is measured in a position which at all times is in contact with a molten film-depositing material of said at least one film-depositing material. Further, it is preferable that said temperature is measured by a temperature measuring means with its probe being placed within said crucible after it is inserted into an electrical insulating protective tube. Furthermore, it is preferable that electrical insulating protective tube has a hole through which said molten film-depositing material flows in.

Further, according to a second aspect of the present invention, there is an apparatus for vacuum deposition, including: a vacuum chamber; evacuating means for evacuating an inside of said vacuum chamber; one or more crucibles for resistance heating, said crucible containing at least one film-depositing material; a power source for resistance heating which supplies said one more crucibles with resistance heating power; temperature measuring means for measuring temperature in an interior of said one crucible or at least one crucible among said more crucibles; and control means for controlling supply of power from said power source for resistance heating to said one or more crucibles in accordance with a measurement result of the temperature of said interior of said one crucible or said at least one crucible with said temperature measuring means, wherein heating of said one or more crucibles is controlled by said control means and a film is formed on a surface of a substrate under controlling of heating of said one or more crucibles.

In the apparatus for vacuum deposition according to the second aspect of the present invention, it is preferable that said heating of said one or more crucibles is performed by applying electric current to said one or more crucibles from said power source to generate heat by themselves. Further, it is preferable that said crucible comprises a film-depositing material containing section having an interior space for containing said at least one film-depositing material which is a substantially closed space and a vapor outlet having an aperture ratio of not more than 10%. Further, it is preferable that aid crucible further comprises a tubular section that surrounds said vapor outlet and which projects from said film-depositing material containing section. Further, it is preferable that a shield member that prevents said at least one film-depositing material from gushing out upon bumping is provided within said film-depositing material containing section. Further, it is preferable that a probe of said temperature measuring means is provided in an area between said shield member and said vapor outlet or on a side of said vapor outlet with respect to said shield member. Further, it is preferable that a probe of said temperature measuring means is provided in a position which at all times is out of contact with a molten film-depositing material of said at least one film-depositing material. Further, it is preferable that a probe of said temperature measuring means is provided in a position which at all times is in contact with a molten film-depositing material of said at least one film-depositing material. Further, it is preferable that said probe of said temperature measuring means is placed within said one crucible or at least one crucible after it is inserted into an electrical insulating protective tube. Furthermore, it is preferable that said electrical insulating protective tube has a hole through which said molten film-depositing material flows in.

In the present invention having the above-described features, temperature measurement is effected in the interior of the crucible (boat) serving as a source of resistance heating, so the temperature of the molten film-depositing material (the source of melt evaporation) can be known in an appropriate way and by controlling the state of heating with the crucible in accordance with the result of this temperature measurement, the amount of evaporation of the film-depositing material, namely, the deposition rate can be controlled in an appropriate way so that an appropriate film having a predetermined thickness can be formed consistently.

Thus, by applying the present invention in the manufacture of storage phosphor sheets that involves the formation of a phosphor layer through vacuum deposition, one can form a high-quality phosphor layer of exact film thickness, enabling consistent manufacture of high-quality storage phosphor sheets that are free from image deterioration and other defects due to errors in film thickness.

### BRIEF DESCRIPTION OF THE DRAWINGS

FIG. 1A is a simplified front view showing the essential parts of an exemplary apparatus for producing a phosphor sheet by making use of the present invention;

FIG. 1B is a simplified side view of the same apparatus;

FIG. 2 is a schematic top view of the thermal evaporating section of the apparatus shown in FIG. 1A;

FIG. 3A is a top view of a crucible in the apparatus shown in FIG. 1A;

FIG. 3B is a simplified front view of the crucible;

FIG. 3C is a simplified side view showing the interior of the crucible; and

FIG. 4 is a simplified sectional view showing another example of the crucible that can be employed in the present invention.

### DETAILED DESCRIPTION OF THE INVENTION

On the following pages, the method and apparatus for vacuum deposition according to the present invention are described in detail with reference to the preferred embodiments shown in the accompanying drawings.

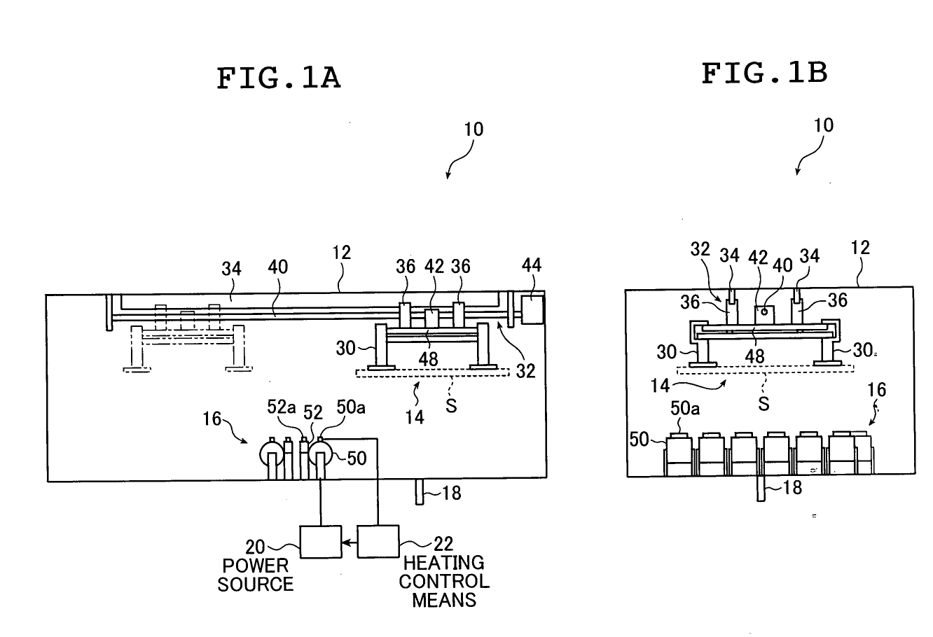

FIGS. 1A and 1B show the concept of an exemplary apparatus for producing a phosphor sheet by making use of the method and apparatus for vacuum deposition according to the present invention; FIG. 1A is a front view of the apparatus and FIG. 1B is its side view. Shown by 10 in FIGS. 1A and 1B is the apparatus for producing a phosphor sheet (which is hereinafter referred to simply as the production apparatus 10); by means of two-source vacuum deposition in which a film-depositing material (evaporation source) that provides a phosphor (matrix) and one that provides an activator are evaporated separately, a layer made of an storage phosphor (which is hereinafter referred to as a phosphor layer) is formed on a surface of a substrate S to produce (an storage) phosphor sheet.

The production apparatus 10 basically includes a vacuum chamber 12, a substrate holding and transporting mechanism 14, a thermal evaporating section 16, and a gas introducing nozzle 18.

Needless to say, the production apparatus 10 may optionally have a plasma generator (ion gun) and various other constituents of known apparatuses for vacuum deposition.

In a preferred version of the illustrated case, cesium bromide (CsBr) serving as the phosphor component and europium bromide [EuBrₓ (x is typically 2 or 3, with 2 being particularly preferred)] serving as the activator component are used as film-depositing materials and two-sources vacuum deposition depending on resistance heating is performed to deposit a phosphor layer of the storage phosphor CsBr:Eu on the substrate S, thereby forming a phosphor sheet. To this end, the thermal evaporating section 16 includes an array of crucibles 50 which serve as resistance heating sources for the phosphor and an array of crucibles 52 which serve as resistance heating sources for the activator.

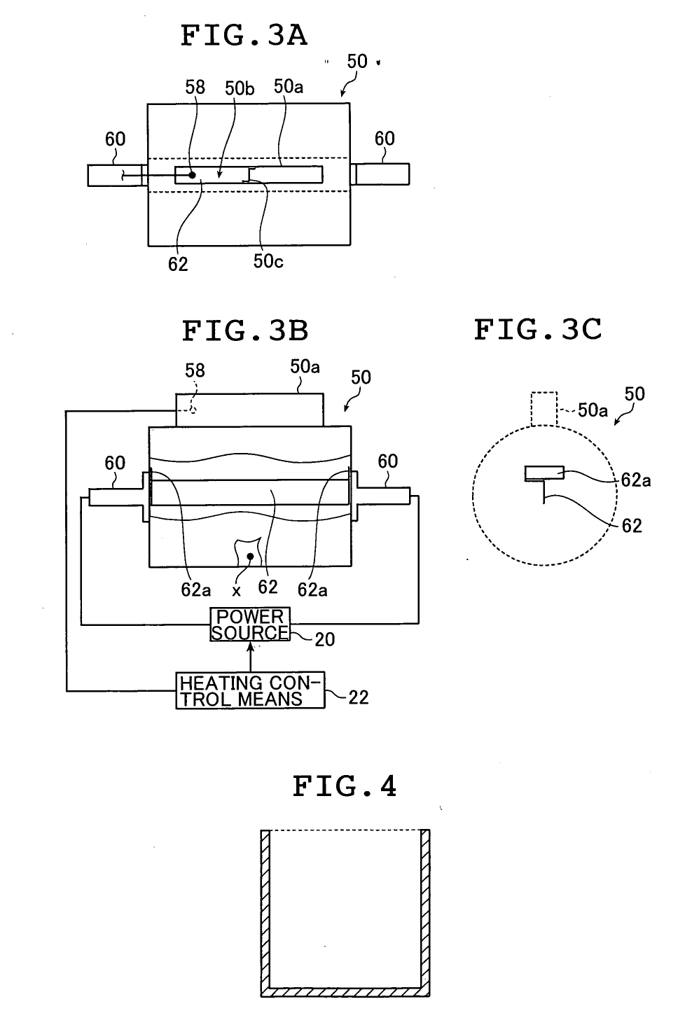

Although not shown in FIG. 1A for simplification and clarification purposes, each of the crucibles 52 is connected to a power source for resistance heating. Each of the crucibles 50 is connected to a power source for resistance heating 20 and a heating control means 22, but these are not shown in FIG. 1B for the same reason as given above. In addition, each of the crucibles 50 is equipped with a thermocouple 58 as shown in FIG. 3A which is referred to later.

The production apparatus 10 having the gas introducing nozzle 18 through which an inert gas is introduced during film deposition is preferably operated as follows: The interior of the vacuum chamber 12 is first evacuated to high degree of vacuum and with continued evacuation, an inert gas such as argon is introduced into the vacuum chamber 12 through the gas introducing nozzle 18 until the pressure in the vacuum chamber 12 is reduced to a medium degree of vacuum in the range of about 0.1 Pa-10 Pa (particularly 0.5-3 Pa) and under this medium degree of vacuum, the film-depositing materials (cesium bromide and europium bromide) are thermally evaporated by resistance heating in the thermal evaporating section 16 as the substrate S is transported linearly by means of the substrate holding and transporting mechanism 14 (this movement is hereinafter sometimes referred to as linear transport), whereby a phosphor layer is formed on the substrate S by vacuum deposition.

By thusly forming a phosphor layer under a medium degree of vacuum with an inert gas being introduced, one can produce a phosphor sheet which is improved in image sharpness and characteristics of photostimulated luminescence on account of the satisfactory columnar crystal structure of the phosphor layer.

In the present invention, CsBr:Eu is not the only storage phosphor (stimulable phosphor) that forms the phosphor layer and various other types may of course be used. To give just one example, an alkali halide based storage phosphor that is disclosed in JP 61-72087 A and represented by the general formula M^{I}X.aM^{II}X′₂.bM^{III}X″₃:cA may preferably be used. In this general formula, M^{I} is at least one member of the group consisting of Li, Na, K, Rb and Cs; M^{II}, is at least one divalent metal selected from the group consisting of Be, Mg, Ca, Sr, Ba, Zn, Cd, Cu and Ni; M^{III}, is at least one trivalent metal selected from the group consisting of Sc, Y, La, Ce, Pr, Nd, Pm, Sm, Eu, Gd, Tb, Dy, Ho, Er, Tm, Yb, Lu, Al, Ga and In; X, X′ and X″ are each independently at least one member of the group consisting of F, Cl, Br and I; A is at least one member of the group consisting of Eu, Tb, Ce, Tm, Dy, Pr, Ho, Nd, Yb, Er, Gd, Lu, Sm, Y, Tl, Na, Ag, Cu, Bi and Mg; 0≦a<0.5; 0≦b<0.5; and 0<c≦0.2.

Other preferred examples are the storage phosphors disclosed in U.S. Pat. No. 3,859,527, JP 55-12142 A, JP 55-12144 A, JP 55-12145 A, JP 59-38278 A, JP 56-116777 A, JP 58-69281 A, JP 59-75200 A, etc.

In particular, for various reasons such as improved characteristics of photostimulated luminescence and sharpness in image reproduction, and on account of the fact that the beneficial effects of the present invention can advantageously be obtained, the aforementioned alkali halide based storage phosphor may be given as a preferred example; particularly preferred is an alkali halide based storage phosphor in which M^{I} contains at least Cs, X contains at least Br, and A is Eu or Bi; most preferred is the above-described CsBr:Eu.

Further, there is no particular limitation on the material of the substrate S and all types of materials for sheet-shaped substrates used in phosphor sheets such as glass, ceramics, carbon, aluminum, PET (polyethylene terephthalate), PEN (polyethylene naphthalate), and polyamide are available. There is also no particular limitation on the shape of the substrate S.

The vacuum chamber 12 may be any known vacuum chamber (e.g. bell jar and vacuum vessel) that is formed of iron, stainless steel, aluminum, etc. and which is employed in apparatuses for vacuum deposition.

The gas introducing nozzle 18 is also a known gas introducing means that has a means of connection to containers and the like, as well as a means for regulating the gas flow rate (the nozzle may alternatively be connected to those means), etc. and which is conventionally employed in apparatuses for vacuum deposition, sputtering, etc. In order to form a phosphor layer by vacuum deposition under the above-defined medium degree of vacuum, an inert gas such as argon or nitrogen gas is introduced into the vacuum chamber 12 through the nozzle 18.

The vacuum chamber 12 is connected to a vacuum pump (not shown).

The vacuum pump is not limited to any particular types, either, and various types of vacuum pumps employed in vacuum deposition apparatuses may be used as long as they can attain the required ultimate degree of vacuum. To mention a few examples, an oil diffusion pump, a cryogenic pump, and a turbo molecular pump may be used, optionally in combination with a cryogenic coil or other auxiliary means. In the production apparatus 10 intended to form the above-described phosphor layer, the ultimate degree of vacuum to be attained in the vacuum chamber 12 is preferably 8.0×10⁻⁴ Pa or less.

The substrate holding and transporting mechanism 14 holds the substrate S and transports it over a linear transport path (this action is hereinafter referred to simply as linear transport) and includes a substrate holding means 30 and a transport means 32.

The transport means 32 is a known mechanism for effecting linear movement by making use of thread-assisted transmission and it essentially includes a linear motor guide having guide rails 34 and catching members 36 that are guided by the guide rails 34, a ball screw having a screw shaft 40 and a nut 42, and a rotational drive source 44 for the screw shaft 40.

The substrate holding means 30 is a known means of holding sheeting; it has an engaging means 48 which engages the nut 42 in the ball screw and the catching members 36 in the linear motor guide, with the substrate S being held at the lower ends. The transport means 32 effects linear movement of the substrate holding means 30 in predetermined directions (right and left in FIG. 1A, and perpendicular to the paper on which FIG. 1B is drawn).

In the illustrated case of the production apparatus 10, the substrate holding means 30, as it holds the substrate S, is transported by the transport means 32 to effect linear transport of the substrate S in the predetermined directions defined above.

In the illustrated case, the substrate S is thus transported linearly whereas a plurality of evaporation sources are arranged in a direction perpendicular to its transport; this contributes to realizing the formation of a phosphor layer having high uniformity in thickness profile. Generally speaking, given the same thickness, the greater the number of passes over the thermal evaporating section 16, the higher the uniformity that can be attained in thickness profile; hence, it is preferred to form a phosphor layer by reciprocating the substrate S a plurality of times. The number of reciprocating movements may be determined as appropriate for the desired thickness of the phosphor layer, the desired uniformity in thickness profile, and other factors. The transport speed may also be determined as appropriate for the limits of transport speed that are rated for the apparatus, the number of reciprocating movements, the desired thickness of the phosphor layer, and other factors.

The thermal evaporating section 16 is provided in the lower part of the vacuum chamber 12.

The thermal evaporating section 16 is a site where the two film-depositing materials, cesium bromide and europium bromide, are evaporated by resistance heating. Although not shown for the reasons already given, shutters are provided above the thermal evaporating section 16 (crucibles 50 and 52) to isolate the vapors of the film-depositing materials coming from that section.

As already mentioned, the production apparatus 10 performs two-sources vacuum deposition as a preferred embodiment in which cesium bromide as the phosphor component and europium bromide as the activator component are heated to evaporate independently. Therefore, the thermal evaporating section 16 has provided therein the crucibles 50 for evaporating cesium bromide (phosphor) and the crucibles 52 for evaporating europium bromide (activator).

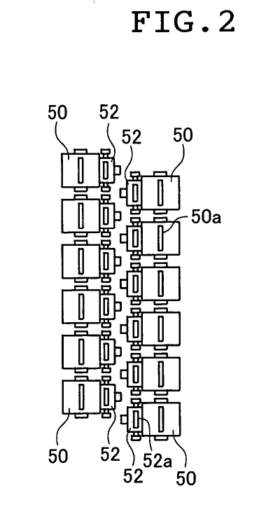

As the simplified top view in FIG. 2 shows, the crucibles 50 (or 52) in the illustrated case are such that six of them are arranged in a direction perpendicular to the direction in which the substrate S is transported (which is hereinafter referred to simply as the direction of transport). Adjacent crucibles are isolated from each other by physical spacing, insertion of an insulator, and any other suitable means.

The crucibles 50 are arranged in two rows, and so are the crucibles 52 in such a way that the two rows of crucibles 52 are positioned between the two rows of crucibles 50 in the direction of transport. Any two crucibles 50 and 52 that are adjacent to each other in the direction of transport make a pair and are arranged parallel to the direction of transport. In addition, the crucible pairs each composed of one crucible 50 and one crucible 52 are staggered in the row direction so as to fill the gap between adjacent crucibles in the row direction (thereby enabling uniform vapor emission in the row direction).

As already mentioned, in the illustrated case of the production apparatus 10, the substrate S undergoes linear transport and the crucibles 50 and 52 for evaporation by resistance heating are arranged in a direction that is perpendicular to the direction of transport; as a result, the entire surface of the substrate S is uniformly exposed to the vapors of the film-depositing materials so as to enable the formation of a phosphor layer having an extremely high uniformity in thickness profile.

To state more specifically, a phosphor layer is formed on the substrate S by vacuum deposition as it is transported linearly and this ensures that the moving speed over the surface of the substrate S (where the phosphor layer is to be deposited) is made uniform across this surface; in addition, a plurality of crucibles (sources of evaporation by resistance heating) are simply arranged linearly in a direction perpendicular to the direction of transport and in spite of this extremely simple arrangement of evaporation sources, the entire surface of the substrate S can be uniformly exposed to the vapors of the film-depositing materials, which contributes to the formation of a phosphor layer having high uniformity in thickness profile. The beneficial effects of these features are particularly significant when vacuum deposition is performed under the medium degree of vacuum as described above, where in order to minimize the collision between the particles of argon or other inert gas and the evaporated film-depositing material, the gap between the substrate and each crucible must be made smaller than in the case of ordinary deposition which is effected under high vacuum but then the vapors of the film-depositing material will directly reach the substrate S before they have sufficiently diffused within the evaporation system.

The features described above offer the additional advantage of allowing the activator component to be dispersed most uniformly within the storage phosphor layer in both directions of its plane and thickness, whereby one can produce a phosphor sheet having good uniformity in sensitivity and the characteristics of photostimulated luminescence.

Like crucibles employed in ordinary vacuum deposition that depends on resistance heating, the crucibles 50 and 52 are formed of high-melting point metals such as tantalum (Ta), molybdenum (Mo) and tungsten (W) and supplied with electricity from electrodes (not shown) to generate heat by themselves so that the film-depositing materials with which the crucibles are filled are heated/melted to evaporate; in other words, the crucibles 50 and 52 themselves serve as sources of resistance heating.

In the storage phosphor, the proportions of the activator and the phosphor are such that the greater part of the phosphor layer is assumed by the phosphor, as exemplified by a molarity ratio ranging from about 0.0005/1 to about 0.01/1.

The crucibles 52 for europium bromide (activator) which is to be deposited in the smaller amount are such that the top faces of usual boat-type crucibles are each closed with a lid having a slit of vapor outlet that extends in a direction parallel to the row direction in which the crucibles are arranged. Fixed at the vapor outlet is a chimney 52a in a rectangular tubular form with an identical cross section having a top and a bottom open side; the vapor of the film-depositing material is emitted through the chimney 52a.

As already mentioned, although not shown, each of the crucibles 52 is connected to a power source for resistance heating. Since the activator is to be vapor-deposited (evaporated) in the smaller amount, constant-current control may be mentioned as an exemplary method of controlling the heating of the crucibles 52. Note that this is not the only method of controlling the heating of the crucibles 52 and various other methods that are employed in vacuum deposition may be adopted, as exemplified by use of a thyristor, a DC method, a thermocouple feedback method, etc.

On the other hand, the crucibles 50 for cesium bromide (phosphor) which is to be deposited in the larger amount are of a large size in drum (cylindrical) shape. Each of the crucibles 50 has a slit of vapor outlet on the side of the drum which extends along the longitudinal axis of the drum. Fixed at the vapor outlet is a chimney 50a in a rectangular tubular form with an identical cross section having a top and a bottom open side; the vapor of the film-depositing material is similarly emitted through the chimney 50a. The crucibles 50 are arranged in a row such that the longitudinal axis of each drum is in alignment with the row direction; in other words, the chimneys 50a in a rectangular tubular form with slits of a top and a bottom open side have their longitudinal direction in alignment with the direction in which the crucibles 50 are arranged in a row.

An advantage of these chimneys (flues through which vapor is emitted) is that when bumping occurs on account of local heating or abnormal heating in the crucibles, abrupt gushing of the film-depositing materials from within the crucibles can be prevented, ensuring that there will be no contamination of the surrounding areas and the substrate S. The beneficial effect of this feature is particularly significant when vacuum deposition is performed under the medium degree of vacuum as described above, in which there is a need to bring the substrate S close enough to the evaporation sources.

In the case under consideration, the crucibles 50 for cesium bromide are such that temperature measurement is performed in their interiors and in accordance with the results of the measurement, heating, or the amount in which the film-depositing materials are evaporated from the individual crucibles (i.e. their deposition rate), is controlled, thereby implementing the method of vacuum deposition according to the present invention.

FIG. 3 shows an outline of the crucible 50 by top view (A), a front view (B) with part taken away (as seen in the same direction as FIG. 1B), and a side view (C) (as seen in the same direction as FIG. 1A).

As already mentioned, the crucible 50 is drum-shaped and has the slit of vapor outlet 50b on the side of the drum which aligns with the longitudinal axis of the drum, and fixed at the vapor outlet 50b is the chimney 50a in a rectangular tubular form having a top and a bottom open side. The chimney 50a is fitted with a generally Z-shaped rib 50c which supports it from the inside to enhance its strength.

The crucible 50 also has a shield member 62 fixed in its interior to ensure that the film-depositing materials will not gush out due to bumping. The shield member 62 is formed of an elongated rectangular sheet in a generally T shape, and the horizontal top bar of the T is bent back to stand vertically at both ends of its length to form mounting portions 62a. The shield member 62 is placed within the crucible (drum) 50 in such a way that the top face of the T shape will close the vapor outlet 50 as it is seen from the above, with the mounting portions 62a being internally fixed to the end faces of the drum.

An electrode 60 is fixed to each end face of the crucible (drum) 50.

Both electrodes 60 are connected to the power source for resistance heating 20 (which is hereinafter referred to simply as the power source 20). The power source 20 is not limited in any particular way and a variety of types can be employed as long as they can cause heat generation from crucibles that serve as sources of resistance heating in vacuum evaporation that depends on resistance heating.

In the illustrated case, a thermocouple 58 as a temperature measuring means is inserted into the chimney 50a on the crucible 50 through a side of that chimney 50a (an end face in the direction in which the slit extends). Note here that in order to ensure that there will be no error in temperature measurement on account of the unwanted weak voltage coming from the power source 20, the thermocouple 58 (or its thermal contact) is preferably placed in a position that avoids contact with the crucible 50. In the illustrated case, the thermocouple 58 is inserted into the chimney 50a through an end face in the direction in which the slit extends; however, this is not the sole case of the present invention and it is also preferred to insert the thermocouple 58 into the chimney 50a through a side face which is parallel to its length.

The crucible 50, in the mode of normal use, is filled with the film-depositing material in such a way that the molten film-depositing material (melt evaporation source) will not contact the shield member 62. Hence, the thermocouple 58 placed within the chimney 50a will in no case contact the melt evaporation source. In this embodiment where the thermocouple 58 performs temperature measurement without contacting the melt evaporation source, the thermal contact of the thermocouple 58 is preferably brought into direct contact with the vapor of the film-depositing material in order to accomplish highly precise temperature measurement.

The thermocouple 58 is connected to the heating control means 22.

In accordance with the result of temperature measurement with the thermocouple 58, the heating control means 22 controls the power being supplied from the power source 20 to the crucible 50 in such a way that the site at which temperature is being measured attains a predetermined temperature. To be more specific, the heating control means 22 performs feedback control in such a way that in accordance with the result of temperature measurement with the thermocouple 58, it controls the heat generation from the crucible 50 (i.e. the heating of the film-depositing material), thereby controlling the amount in which the film-depositing material is being evaporated.

According to the present invention, vacuum deposition that depends on resistance heating is performed in such a way that temperature measurement is effected in the interior of a crucible which serves as a source of resistance heating, and in accordance with the result of the temperature measurement, the heating of the crucible, namely, the amount in which the film-depositing material is being evaporated (i.e. the deposition rate), is controlled. As a result, without being affected by any external effects such as the heat of radiation from an adjacent crucible, the temperature of the film-depositing material can be known in a sufficiently consistent and appropriate manner to ensure that feedback control is appropriately performed in such a way that the amount in which the film-depositing material is being evaporated, namely, the deposition rate is correctly controlled to ensure consistent formation of phosphor layers having a predetermined thickness.

The vapor of the film-depositing material gets its temperature to drop as soon as it is emitted from the crucible and the amount of the temperature drop is also variable since it is subject to a variety of effects. In addition, in the illustrated case of an apparatus for vacuum evaporation where a plurality of crucibles are heated simultaneously, the method of measuring the temperature of the outer bottom surface of a crucible as disclosed in JP 6-158287 A or the methods of measuring the temperature of the atmosphere in the internal space of a vacuum chamber as disclosed in JP 7-331421 A and JP 2000-34559 A have the disadvantage that the results of temperature measurement are affected by external factors such as the heat of radiation from other crucibles to become inconsistent, making it impossible to perform feedback control in an appropriate manner.

It should be noted here that the crucible is a source of resistance heating and it has also generated heat by itself. Therefore, even if it has an open top as shown in FIG. 4, temperature can be measured in its interior without receiving external effects such as the heat of radiation from other crucibles and the environment within the vacuum chamber, as exemplified by the gas to be introduced. Thus, measuring the temperature in the interior of the crucible offers the advantage that even if it is performed without contact with the melt evaporation source, the temperature of the melt evaporation source can be known in a sufficiently consistent and appropriate manner to ensure that feedback control is appropriately performed, whereby a predetermined deposition rate is assured to enable the formation of phosphor layers (vacuum evaporated films) having the correct thickness.

The term “the interior of the crucible” as used in the present invention means the inside area of the crucible which is inward of the plane defined by the opening through which the vapor of the film-depositing material is emitted. Hence, in the case of the crucible 50 shown in FIGS. 3A-3C, its inside area which is inward of the top open side of the chimney 50a is the interior of the crucible, and in the case of the cup-shaped crucible shown in FIG. 4, its inside area which is inward of the top open side of the cup (the plane indicated by the dashed line) is the interior of the crucible.

In the present invention, the position at which the thermocouple (thermal contact) is to be placed (namely, the position of temperature measurement) is not limited to the position where it does not contact the melt evaporation source; in another advantageous embodiment, the thermocouple may be placed at a position where it keeps contact with the melt evaporation source, as exemplified by the neighborhood of the bottom of the crucible 50 which is indicated by symbol x in FIG. 3B, and the result of temperature measurement with that thermocouple is fed back to control the heat generation from the crucible 50.

In this case, too, in order to ensure that there will be no error in temperature measurement due to the unwanted small voltage coming from the power source 20, the crucible 50 is preferably kept away from the thermal contact of the thermocouple 58. Therefore, in the embodiment under consideration where the thermocouple 58 is kept in contact with the melt evaporation source, the thermocouple 58 is preferably placed within the crucible 50 after it is inserted into a protective tube that is an electrical insulator and is sufficiently heat-resistant, as exemplified by a ceramic (e.g. aluminosilicate glass) protective tube. If such a protective tube is to be used, it is preferably provided with a hole through which the melt evaporation source can flow in so that it makes direct contact with the thermocouple 58. The protective tube with the hole permits the thermal contact of the thermocouple to be directly exposed to the vapor of the film-depositing material, so it can also be employed in the aforementioned case of performing temperature measurement with the thermocouple that does not contact the melt evaporation source.

Alternatively, it is also preferred to coat the thermocouple 58 with an electrical insulating and heat-resistant film such as one that is made of alumina.

In the present invention, the position of the thermal contact of the thermocouple 58 (the position of temperature measurement) is not limited to the positions described above and a variety of positions can be adopted as long as they are in the interior of the crucible and preferably make no contact with the crucible. However, in order to ensure consistent and appropriate results, temperature measurement is preferably performed with the thermocouple being placed in a position where in no case will it contact the melt evaporation source or in a position where it is kept in contact with the melt evaporation source.

Therefore, in the illustrated case of the crucible 50 which is adapted to have the shield member 62 to prevent the film-depositing material from gushing out due to bumping, if one wants to perform temperature measurement without having contact with the molten film-depositing material, the thermocouple 58 is preferably placed in a position above the shield member 62. In this case of temperature measurement that involves no contact with the melt evaporation source, a shelf may be provided within the crucible in order to eliminate the adverse effect of the heat of radiation from the melt evaporation source.

In the present invention, the shape of the crucible is not limited to the illustrated case where its main body assumes a drum shape with the vapor outlet 50b provided to define a generally closed space which is to be filled with the film-depositing material (in other words, the crucible has such a shape that it covers substantially the entire liquid surface of the molten film-depositing material) and various shapes of crucibles can be adopted.

An example that can be used is a cup-shaped crucible having a fully open topside as shown in FIG. 4; one may measure the temperature in this crucible and perform feedback control of heating. Alternatively, one may use a so-called “boat-type” crucible, measure the temperature in this crucible, and perform feedback control of heating.

Note that in order to perform temperature measurement in a more consistent and appropriate way, it is preferred to use a crucible whose area to be filled with the film-depositing material is a generally closed space, as exemplified by the illustrated case of crucible 50.

Specifically, it is preferred to use a crucible having an aperture ratio of not more than 10%, which means that the area of the vapor outlet accounts for 10% or less of the surface area of the space to be filled with the film-depositing material which may well be called the main body of the crucible. In the illustrated case of crucible 50, the area of the vapor outlet 50b preferably accounts for not more than 10% of the entire surface area of the drum excepting the chimney 50a.

In the present invention, the means of temperature measurement is not limited to the thermocouple and various types of means for temperature measurement can be employed as long as they can perform temperature measurement in the interior of the crucible.

As already mentioned, the activator is deposited (evaporated) in such a small amount that in the illustrated case, thermal evaporation in the crucible 52 for the activator is subjected to constant-current control; however, this is not the sole case of the present invention and as will be described later in the Examples, the crucible 52 for the activator may of course be handled by the vacuum deposition method of the present invention, in which temperature is measured within the crucible and in accordance with the result of this measurement, heating and, hence, the deposition rate is controlled.

The illustrated case concerns a preferred embodiment in which all the crucibles 50 for the phosphor are subjected to temperature measurement and in response to the result, feedback control is performed on heating. This is not the sole case of the present invention and crucibles' heating may be controlled on the basis of temperature measurement that is performed in one out of a specified number of crucibles, say, in every second crucibles, in every third crucibles, and so on. In this alternative case, the control of heating may be performed for individual crucibles or heating may be controlled for each group of crucibles that have been collectively subjected to temperature measurement. In the case of performing temperature measurement in one out of a specified number of crucibles and if as many crucibles as in the illustrated case are used, it goes without saying that temperature measurement is effected at crucibles spaced apart from each other at specified intervals.

On the following pages, a description is made as to how the production apparatus 10 is operated to form a phosphor layer on the substrate S (to eventually produce a phosphor sheet).

First, the vacuum chamber 12 is opened. Then, the substrate S is held on the substrate holding means 30 in the substrate holding and transporting mechanism 14 and all the crucibles 50 are charged with a predetermined amount of cesium bromide whereas all the crucibles 52 are charged with a predetermined amount of europium bromide; thereafter, the shutters are closed and the vacuum chamber 12 is also closed.

In the next step, the evacuating means is activated to evacuate the vacuum chamber 12; at the time when the pressure in the vacuum chamber has reached a predetermined value, say, 8×10⁻⁴ Pa, argon gas is introduced into the vacuum chamber 12 through the gas introducing nozzle 18 with the evacuating process being continued such that the pressure in the vacuum chamber 12 is adjusted to an elevated value, say, 1 Pa; thereafter, the power source for resistance heating is turned on so that an electric current is passed through all the crucibles 50 and 52 to heat the film-depositing materials; after the lapse of a predetermined period of time, the rotational drive source 44 is driven to start transport of the substrate S; then, the shutters are opened to start the formation of a phosphor layer on the surface of the substrate S.

During film deposition, the temperature in all the crucibles 50 is measured with the thermocouples 58 and in accordance with the result, the heating control means 22 controls the power from the power source 20 to, the crucibles 50 such that a predetermined temperature is reached, whereby the amount in which the film-depositing material is evaporated from each crucible 50 is controlled to regulate the deposition rate.

When a specified number of reciprocating movements of the substrate S for its linear transport as determined in accordance with such factors as the thickness of the phosphor layer to be formed have completed, the substrate S is brought to a stop, the shutters are closed, the power source for resistance heating is turned off, the supply of argon gas through the nozzle 18 is stopped, dried nitrogen gas or dry air is introduced into the vacuum chamber 12 to restore atmospheric pressure; then, the vacuum chamber is opened and the substrate S having a phosphor layer formed thereon is taken out as the product phosphor sheet.

The phosphor sheet thus prepared has the phosphor layer formed with the deposition rate having been controlled in accordance with the results of temperature measurement in the interiors of the crucibles 50. Hence, it is a high-quality product having the phosphor layer deposited at the appropriate deposition rate to have a thickness of high precision.

While the method and apparatus of the present invention for vacuum deposition have been described above in detail, the invention is by no means limited to the foregoing embodiments and it should be understood that various improvements and modifications can of course be made without departing from the scope and spirit of the invention.

In the foregoing embodiments, the apparatus is of a type that performs two-sources vacuum deposition in which two kinds of film-depositing materials are heated in separate crucibles, but this is not the sole case of the invention and one may employ an apparatus that performs one-source vacuum deposition with all necessary film-depositing materials being mixed and accommodated in a single evaporation source. If desired, apparatuses capable of multi-source vacuum deposition in which three or more components are deposited may be employed. In the illustrated case, more than one crucible is provided for each of the film-depositing materials; again, this is not the sole case of the invention and only one crucible may be used for each of the film-depositing materials, or alternatively, a certain film-depositing material may be accommodated in a single crucible whereas more than one crucible is provided for the other film-depositing materials.

In addition, the foregoing embodiments relate to the application of the present invention to the deposition of phosphor layers in the manufacture of phosphor sheets, but this again is not the sole case of the invention and it may be applied to the deposition of various kinds of films other than the phosphor layer by means of vacuum deposition.

Furthermore, the illustrated case of apparatus for vacuum deposition performs film deposition on the substrate as it undergoes linear transport but again this is not the sole case of the invention and the apparatus may be replaced by a so-called substrate rotating type which performs film deposition on the substrate as it rotates either on its own axis, or around some other element, or both on its axis and around some other element.

On the following pages, the present invention is described in greater detail with reference to specific examples.

### COMPARATIVE EXAMPLE 1-1

Cesium bromide (CsBr) powder having a purity of 4 N or more was provided as a film-depositing material.

Analysis of trace elements in the CsBr powder by ICP-MS (inductively coupled plasma spectrometry-mass spectrometry) showed that the alkali metals other than Cs in CsBr (i.e. Li, Na, K, and Rb) were each present in not more than 10 ppm whereas other elements such as alkaline earth metals (Mg, Ca, Sr, and Ba) were each present in 2 ppm or less. Since the CsBr powder was highly hygroscopic, it was stored in a desiccator keeping a dry atmosphere with a dew point of −20° C. or lower and taken out just before use.

A 0.7 mm thick glass sheet was provided as a substrate S.

This substrate S was mounted on the substrate holding means 30 in the production apparatus 10, with the distance between the substrate S and each crucible 50 adjusted to 15 cm.

Then, the film-depositing material CsBr was filled into each of the crucibles 50 (made of Ta). A type R (Pt—Rh) thermocouple 58 was secured in contact with the bottom (outer surface) of each crucible 50 to enable measurement of its temperature.

After the mounting of the substrate S and charging of CsBr had been completed, the vacuum chamber 12 was closed and the main evacuation valve was opened until the apparatus was evacuated to 2×10⁻³ Pa. The evacuation unit was the combination of a rotary pump, a mechanical booster and a diffusion pump. To remove water, a moisture purging cryogenic pump was employed.

Thereafter, the main evacuation valve was closed and the bypass was actuated to introduce Ar gas into the vacuum chamber 12 through the gas introducing nozzle 18 until it had a pressure of 1.0 Pa.

Subsequently, the substrate transport means 32 was actuated to start transport (reciprocating transport) of the substrate S; at the same time, the power source 20 was turned on to apply an electric current to the crucibles 50 so that CsBr was thermally melted. In accordance with the results of temperature measurement with thermocouples attached to the bottoms of the crucibles 50, the heating (or the voltage applied from the power source 20 to each crucible 50) was feedback controlled by the heating control means 22 so that the temperature of each crucible 50 would be held constant at 690° C.

When the temperature of the crucibles 50 had stabilized at the preset value (690° C.), the shutters were opened and a CsBr phosphor matrix layer was formed on the surface of the substrate S. The deposition time was 60 minutes.

After the end of the deposition, nitrogen gas was introduced into the vacuum chamber 12 to restore an atmospheric pressure in it and the substrate S was taken out of the production apparatus 10. The substrate S had a deposited coating layer (with an area of 20 cm×20 cm) which consisted of substantially vertical columnar crystals of CsBr standing on end at close spacings.

Thereafter, the crucibles 50 were replaced and the same procedure of film deposition as described above was repeated three more times to prepare a total of four samples of the substrate S having the CsBr phosphor matrix layer formed thereon.

### COMPARATIVE EXAMPLE 1-2

A quartz crystal oscillating deposition controller (CRTM-9000 of ULVAC, Inc.) was used to measure the amount of CsBr evaporation from each of the crucibles 50.

A CsBr phosphor matrix layer was formed on the substrate S by repeating the procedure of Comparative Example 1-1, except that using the controller, the heating of the crucibles 50 was feedback controlled so that the amount of CsBr evaporation from the crucibles 50 was held constant at 500 Å/s. Again, a total of four samples were prepared.

### EXAMPLE 1-1

A CsBr phosphor matrix layer was formed on the substrate S by repeating the procedure of Comparative Example 1-1, except that temperature measurement was conducted with a type R (Pt—Rh) thermocouple 58 (thermal contact) placed within a chimney 50a as shown in FIG. 3B and that based on the result of the temperature measurement, the heating was feedback controlled by the heating control means 22 so that the temperature was held constant at 690° C. Again, a total of four samples were prepared.

### EXAMPLE 1-2

A CsBr phosphor matrix layer was formed on the substrate S by repeating the procedure of Example 1-1, except that the thermocouple 58 was in a position keeping contact with the melt evaporation source as indicated by x in FIG. 3B. Again, a total of four samples were prepared.

### EXAMPLE 1-3

A CsBr phosphor matrix layer was formed on the substrate S by repeating the procedure of Example 1-2, except that the thermocouple 58 was inserted into an alumina protective tube (o.d. 6 mm; i.d. 4 mm) before it was placed in the crucible 50. A hole 3 mm in diameter was made in the tip of the protective sheath to allow the melt evaporation source to flow in. Again, a total of four samples were prepared.

For each of the thus prepared CsBr phosphor matrix layers, the thickness of the thickest portion was measured and divided by the deposition time to calculate the deposition rate. The percentage of a half of the difference between the maximum (Max) and minimum (Min) values of the deposition rate as relative to the average of the maximum and minimum values of the deposition rate was calculated by the formula: [(Max−Min)/2]/[Max+Min)/2]×100 and the result was used as an index for evaluating dispersion. The data obtained are shown in Table 1 below.

TABLE 1

| | How to control | Deposition rate (μm/min) | | | | | |
|---|---|---|---|---|---|---|---|
| | heating of | | | | | Av- | Disper- |
| | crucibles | 1 | 2 | 3 | 4 | erage | sion |
| CEx. | Temperature of | 9.37 | 10.54 | 9.88 | 8.12 | 9.48 | ±12.97% |
| 1-1 | crucible's | | | | | | |
| | outer bottom | | | | | | |
| | kept constant | | | | | | |
| CEx. | Quartz crystal | 12.76 | 9.94 | 7.20 | 13.18 | 10.77 | ±29.34% |
| 1-2 | oscillating | | | | | | |
| | deposition | | | | | | |
| | controller | | | | | | |
| Ex. | Temperature of | 7.80 | 8.08 | 7.92 | 8.10 | 7.98 | ±1.88% |
| 1-1 | vapor stream | | | | | | |
| | kept constant | | | | | | |
| Ex. | Temperature of | 9.94 | 9.69 | 9.31 | 9.37 | 9.58 | ±3.23% |
| 1-2 | molten liquid | | | | | | |
| | feed kept | | | | | | |
| | constant | | | | | | |
| Ex. | Temperature of | 10.43 | 10.77 | 10.12 | 10.26 | 10.40 | ±3.11% |
| 1-3 | molten liquid | | | | | | |
| | feed kept | | | | | | |
| | constant | | | | | | |

### COMPARATIVE EXAMPLE 2-1

Cesium bromide (CsBr) powder having a purity of 4 N or more and a molten product of europium bromide (EuBr₂) having a purity of 3N or more were provided as film-depositing materials. In order to prevent oxidation, the molten product of EuBr₂ was prepared in a Pt crucible within a tube furnace that had been fully purged with a halogen atmosphere; the process of preparation included heating to 800° C., cooling and taking out of the furnace.

Analysis of trace elements in each of the film-depositing materials by ICP-MS showed the following: The alkali metals other than Cs in CsBr (i.e. Li, Na, K, and Rb) were each present in not more than 10 ppm whereas other elements such as alkaline earth metals (Mg, Ca, Sr, and Ba) were each present in 2 ppm or less; the rare earth elements other than Eu in EuBr₂ were each present in not more than 20 ppm and the other elements in 10 ppm or less.

Since both film-depositing materials were highly hygroscopic, they were stored in a desiccator keeping a dry atmosphere with a dew point of −20° C. or lower and taken out just before use.

A 1 mm thick aluminum sheet (rolled product of SUMITOMO LIGHT METAL INDUSTRIES, LTD. having the designation SL) was electropolished to have a smooth surface (surface roughness Rₐ: 0.048 μm) and it was used as substrate S.

The substrate S was degreased with a weakly alkaline washing solution containing a surfactant, washed with deionized water, dried, and subsequently mounted on the substrate holding means 30 in the production apparatus 10. The distance between the substrate S and each crucible was kept at 15 cm.

The two film-depositing materials were filled in separate crucibles (made of Ta) for resistance heating. Both crucibles were cup-shaped as shown in FIG. 4 and they were arranged in substantially the same positions as the crucibles 50 and 52 shown in FIG. 2.

After the mounting of the substrate S and charging of the two film-depositing materials had been completed, the vacuum chamber 12 was closed and the main evacuation valve was opened until the apparatus was evacuated to 2×10⁻³ Pa. The evacuation unit was the combination of a rotary pump, a mechanical booster and a diffusion pump. To remove water, a moisture purging cryogenic pump was employed.

Thereafter, the main evacuation valve was closed and the bypass was actuated to introduce Ar gas into the vacuum chamber 12 through the gas introducing nozzle 18 until it had a pressure of 0.5 Pa. In addition, a plasma generator (ion gun) as a separate attachment was operated to generate an Ar plasma which was applied to clean the substrate's surface.

After the cleaning step, the main evacuation valve was opened again to draw a vacuum to 1×10⁻³ Pa. Thereafter, the main evacuation valve was again closed and the bypass was actuated to introduce Ar gas into the vacuum chamber 12 thorough the gas introducing nozzle 18 until it had a pressure of 1.0 Pa.

Subsequently, the substrate transport means 32 was actuated to start transport (reciprocating transport) of the substrate S; at the same time, the power source for resistance heating was turned on to apply an electric current to each type of crucibles so that the film-depositing materials were thermally melted. The heating of each crucible was controlled by a constant-current method.

After the end of the melting step, only the shutters above the CsBr crucibles were opened and a CsBr phosphor matrix was built up on the surface of the substrate S to form a coating layer; three minutes later, the shutters above the EuBr₂ crucibles were opened to form a CsBr:Eu phosphor layer on the coating layer. The deposition time was 60 minutes.

After the end of the deposition, nitrogen gas was introduced into the vacuum chamber 12 to restore an atmospheric pressure in it and the substrate S was taken out of the production apparatus 10. Subsequently, heat treatment was conducted at 200° C. for 2 hours in a nitrogen atmosphere to prepare a (storage) phosphor sheet.

The substrate S with the coating layer of CsBr had a deposited layer (thickness: ca. 600 μm; area: 20 cm×20 cm) that consisted of substantially vertical columnar crystals of CsBr:Eu standing on end at close spacings.

Thereafter, the crucibles were replaced and the same procedure of sheet preparation as described above was repeated four more times to prepare a total of five samples of phosphor sheet.

### COMPARATIVE EXAMPLE 2-2

A type R (Pt-Rd) thermocouple was secured in contact with the bottom (outer surface) of each crucible in such a way as to enable temperature measurement.

A phosphor sheet was prepared by repeating the procedure of Comparative Example 2-1 except that based on the results of temperature measurement with the thermocouples, the voltage applied to each crucible was feedback controlled such that the temperature of the CsBr crucibles would be held constant at 700° C. and the temperature of the EuBr₂ crucibles at 900° C. Again, a total of five samples of phosphor sheet were prepared.

### EXAMPLE 2-1

A type R (Pt—Rh) thermocouple was inserted into an alumina protective tube (o.d. 6 mm; i.d. 4 mm), which was then inserted into each crucible to a sufficiently deep position to allow the thermal contact of the thermocouple to be located within the melt evaporation source at all times.

A phosphor sheet was prepared by repeating the procedure of Comparative Example 2-2 except that the voltage applied to each crucible was feedback controlled on the basis of the results of temperature measurement with the thermocouples inserted into the protective sheaths. Again, a total of five samples of phosphor sheet were prepared.

### EXAMPLE 2-2

A phosphor sheet was prepared by repeating the procedure of Example 2-1 except that the thermocouples were not placed in protective tube but had their surface coated with alumina. Again, a total of five samples of phosphor sheet were prepared.

### EXAMPLE 3-1

A phosphor sheet was prepared by repeating the procedure of Example 2-1 except that only the heating of EuBr₂ was controlled by a constant-current method. Again, a total of five samples of phosphor sheet were prepared.

For each of the phosphor sheets prepared, the weight (mg) of the phosphor layer was measured and divided by the substrate's area (400 cm² ) and the deposition time to calculate the deposition rate.

The phosphor layer on each of the phosphor sheets was sampled and dissolved in a dilute nitric acid solution to prepare a solution having a Cs concentration of 2000 ppm. The solution was subjected to quantitative Eu analysis by ICP on an emission plasma analyzer and from the result, Eu/Cs molar ratio in the phosphor layer (CsBr:Eu deposited film) was calculated; the standard deviation σ was determined by the following equation:
σ=√{[nΣx²−(Σx)²)]/[n(n−1)]}

The results are shown in Table 2 below.

TABLE 2

| | How to control | Deposition rate [mg/(cm² × min)] | | | | | | |
|---|---|---|---|---|---|---|---|---|
| | heating of | | | | | | Av- | |
| | crucibles | 1 | 2 | 3 | 4 | 5 | erage | σ |
| CEx. | Constant | 7.50 | 8.47 | 9.30 | 7.64 | 9.18 | 8.42 | 0.84 |
| 2-1 | current | | | | | | | |
| CEx. | Temperature of | 8.58 | 8.03 | 7.98 | 8.92 | 8.69 | 8.44 | 0.42 |
| 2-2 | crucible's | | | | | | | |
| | outer bottom | | | | | | | |
| | kept constant | | | | | | | |
| Ex. | Temperature of | 8.33 | 8.50 | 8.42 | 8.24 | 8.28 | 8.35 | 0.11 |
| 2-1 | molten liquid | | | | | | | |
| | feed kept | | | | | | | |
| | constant | | | | | | | |
| Ex. | Temperature of | 8.45 | 8.39 | 8.50 | 8.43 | 8.36 | 8.43 | 0.05 |
| 2-2 | molten liquid | | | | | | | |
| | feed kept | | | | | | | |
| | constant | | | | | | | |
| Ex. | Temperature of | 8.48 | 8.56 | 8.35 | 8.25 | 8.42 | 8.41 | 0.12 |
| 3-1 | molten liquid | | | | | | | |
| | feed kept | | | | | | | |
| | constant/ | | | | | | | |
| | constant | | | | | | | |
| | current | | | | | | | |
| | How to control | Eu/Cs molar ratio (×10⁻³) | | | | | | |
| | heating of | | | | | | Av- | |
| | crucibles | 1 | 2 | 3 | 4 | 5 | erage | σ |
| CEx. | Constant | 0.76 | 1.85 | 0.95 | 1.54 | 1.35 | 1.29 | 0.44 |
| 2-1 | current | | | | | | | |
| CEx. | Temperature of | 1.26 | 0.78 | 0.93 | 1.03 | 1.47 | 1.09 | 0.27 |
| 2-2 | crucible's | | | | | | | |
| | outer bottom | | | | | | | |
| | kept constant | | | | | | | |
| Ex. | Temperature of | 1.06 | 0.93 | 1.25 | 0.89 | 1.03 | 1.03 | 0.14 |
| 2-1 | molten liquid | | | | | | | |
| | feed kept | | | | | | | |
| | constant | | | | | | | |
| Ex. | Temperature of | 0.92 | 0.93 | 1.08 | 1.12 | 1.20 | 1.05 | 0.12 |
| 2-2 | molten liquid | | | | | | | |
| | feed kept | | | | | | | |
| | constant | | | | | | | |
| Ex. | Temperature of | 1.78 | 1.54 | 0.83 | 0.92 | 1.22 | 1.26 | 0.4 |
| 3-1 | molten liquid | | | | | | | |
| | feed kept | | | | | | | |
| | constant/ | | | | | | | |
| | constant | | | | | | | |
| | current | | | | | | | |

As is clear from the data shown in Tables 1 and 2, the deposition rate varies greatly in the Comparative Examples where it was controlled by the constant-current method, the quartz crystal oscillating deposition controller or the temperature control at the crucible's outer bottom. This may be explained as follows: On account of adverse effects such as the heat of radiation from other crucibles, the amount of evaporation and the temperatures of the melt evaporation sources cannot be known in an appropriate manner, so no appropriate feedback control can be performed; since this prevents accurate control of the deposition rate, the deposited film thickness would vary greatly between successive cycles of film deposition even if each cycle continues for the same period of time.

In contrast, according to the present invention where temperature measurement is conducted within crucibles, the temperatures of the melt evaporation sources can be known in an appropriate and consistent manner and by performing feedback control on the basis of the obtained temperature data, vacuum deposition can be performed at an accurately controlled deposition rate.

Therefore, the above results clearly show the beneficial effects of the present invention.

What is claimed is:

1. A method of vacuum deposition involving resistance heating, comprising the steps of:
measuring temperature in an interior of a crucible for the resistance heating which contains at least one film-depositing material;
controlling heating of said crucible in accordance with a measurement result of the temperature of said interior of said crucible; and
forming a film on a surface of a substrate under controlling of the heating of said crucible.

2. The method of vacuum deposition according to claim 1, wherein said heating of said crucible is performed by applying electric current to said crucible from a power source to generate heat by itself.

3. The method of vacuum deposition according to claim 1, wherein said crucible comprises a film-depositing material containing section having an interior space for containing said at least one film-depositing material which is a substantially closed space and a vapor outlet having an aperture ratio of not more than 10%.

4. The method of vacuum deposition according to claim 3, wherein said crucible further comprises a tubular section that surrounds said vapor outlet and which projects from said film-depositing material containing section.

5. The method of vacuum deposition according to claim 3, wherein a shield member that prevents said at least one film-depositing material from gushing out upon bumping is provided within said film-depositing material containing section.

6. The method of vacuum deposition according to claim 4, wherein said temperature in said interior of said crucible is measured in an area between said shield member, and said vapor outlet or on a side of said vapor outlet with respect to said shield member.

7. The method of vacuum deposition according to claim 1, wherein said temperature in said interior of said crucible is measured in a position which at all times is out of contact with a molten film-depositing material of said at least one film-depositing material.

8. The method of vacuum deposition according to claim 1, wherein said temperature in said interior of said crucible is measured in a position which at all times is in contact with a molten film-depositing material of said at least one film-depositing material.

9. The method of vacuum deposition according to claim 8, wherein said temperature is measured by a temperature measuring means with its probe being placed within said crucible after it is inserted into an electrical insulating protective tube.

10. The method of vacuum deposition according to claim 9, wherein said electrical insulating protective tube has a hole through which said molten film-depositing material flows in.

11. An apparatus for vacuum deposition, comprising:
a vacuum chamber;
evacuating means for evacuating an inside of said vacuum chamber;
one or more crucibles for resistance heating, said crucible containing at least one film-depositing material;
a power source for resistance heating which supplies said one more crucibles with resistance heating power;
temperature measuring means for measuring temperature in an interior of said one crucible or at least one crucible among said more crucibles; and
control means for controlling supply of power from said power source for resistance heating to said one or more crucibles in accordance with a measurement result of the temperature of said interior of said one crucible or said at least one crucible with said temperature measuring means,
wherein heating of said one or more crucibles is controlled by said control means and a film is formed on a surface of a substrate under controlling of heating of said one or more crucibles.

12. The apparatus for vacuum deposition according to claim 11, wherein said heating of said one or more crucibles is performed by applying electric current to said one or more crucibles from said power source to generate heat by themselves.

13. The apparatus for vacuum deposition according to claim 11, wherein said crucible comprises a film-depositing material containing section having an interior space for containing said at least one film-depositing material which is a substantially closed space and a vapor outlet having an aperture ratio of not more than 10%.

14. The apparatus for vacuum deposition according to claim 13, wherein said crucible further comprises a tubular section that surrounds said vapor outlet and which projects from said film-depositing material containing section.

15. The apparatus for vacuum deposition according to claim 13, wherein a shield member that prevents said at least one film-depositing material from gushing out upon bumping is provided within said film-depositing material containing section.

16. The apparatus for vacuum deposition according to claim 15, wherein a probe of said temperature measuring means is provided in an area between said shield member and said vapor outlet or on a side of said vapor outlet with respect to said shield member.

17. The apparatus for vacuum deposition according to claim 11, wherein a probe of said temperature measuring means is provided in a position which at all times is out of contact with a molten film-depositing material of said at least one film-depositing material.

18. The apparatus for vacuum deposition according to claim 11, wherein a probe of said temperature measuring means is provided in a position which at all times is in contact with a molten film-depositing material of said at least one film-depositing material.

19. The apparatus for vacuum deposition according to claim 18, wherein said probe of said temperature measuring means is placed within said one crucible or at least one crucible after it is inserted into an electrical insulating protective tube.

20. The apparatus for vacuum deposition according to claim 19, wherein said electrical insulating protective tube has a hole through which said molten film-depositing material flows in.
